(19) United States
(12) Patent Application Publication
(10) Pub. No.: US 2006/0175685 A1
(43) Pub. Date: Aug. 10, 2006

(54) Composition for forming low-dielectric constant film comprising fullerene, low-dielectric constant film formed from the composition and method for forming the low-dielectric constant film

(75) Inventors: Hyeon Jin Shin, Suwon-si (KR); Hyun Dam Jeong, Suwon-si (KR); Jong Baek Seon, Yeongin-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG CORNING CO., LTD., Suwon-si (KR)

(21) Appl. No.: 11/347,238

(22) Filed: Feb. 6, 2006

(30) Foreign Application Priority Data
Feb. 7, 2005 (KR) 2005-11405

(51) Int. Cl. H01L 23/58; H01L 21/31

(52) U.S. Cl. 257/632; 438/778

(57) ABSTRACT

A composition for forming a low-dielectric constant film comprising a substituted fullerene, a low-dielectric constant film formed from the composition, and a method for forming the low-dielectric constant film are provided. The low-dielectric constant film has superior mechanical properties, such as hardness and elastic modulus, and excellent thermal conductivity.

### BACKGROUND OF THE INVENTION

This non-provisional application claims the benefit of priority under 35 U.S.C. § 119(a) of Korean Patent Application No. 2005-11405 filed on Feb. 7, 2005, which is herein incorporated by reference.

1. Field of the Disclosure

The present disclosure relates to a composition for forming a low-dielectric constant film, a low-dielectric constant film formed from the composition, and a method for forming the low-dielectric constant film. More particularly, the present disclosure relates to a composition for forming a low-dielectric constant film comprising a substituted fullerene wherein the composition can be used to form a low-dielectric constant film having superior mechanical properties and thermal conductivity, a low-dielectric constant film formed from the composition, and a method for forming the low-dielectric constant film.

2. Description of the Related Art

With recent advances in semiconductor manufacturing technology, semiconductor devices have become smaller in size and more densely integrated. Such trends are likely to continue. The degree of integration of devices in the fields of semiconductors refers to the number of constituent devices formed in a single semiconductor chip and indicates how many logic devices (which are fabricated by integrating multifunctional devices, e.g., diodes, resistors and transistors) are included in one chip. That is, the higher the degree of integration, the better the performance. However, as devices are more highly integrated, various factors, such as metal interconnections, may affect the performance of the devices. In addition, interlayer dielectric films having a low charge capacity are required in order to lower the resistance and capacity in interconnections. For this purpose, attempts have been made to use low-dielectric constant materials for interlayer dielectric films. For instance, U.S. Pat. Nos. 3,615,272, 4,399,266 and 4,999,397 disclose polysilsesquioxanes having a dielectric constant of about 2.5˜3.1 which can be applied by spin-on deposition (“SOD”), which can replace SiO₂ having a dielectric constant of around 4.00 applied by a conventional chemical vapor deposition (CVD) technique. Further, U.S. Pat. No. 5,965,679 teaches polyphenylenes as organic polymers having a dielectric constant between about 2.65 and about 2.70. However, this dielectric constant range is not sufficiently low to satisfy an increasing demand to fabricate high-speed devices requiring an ultra-low dielectric constant not higher than 2.50. For this reason, there have been a number of trials to incorporate air having a dielectric constant of 1.0 into the organic or inorganic film-forming materials.

U.S. Pat. No. 6,231,989 discloses a method forming a porous thin film by mixing hydrogen silsesquioxane with a high boiling point solvent capable of forming pores, and treating the mixture with ammonia. Methods for forming an insulator with an ultra-low dielectric constant are found in U.S. Pat. Nos. 6,093,636 and 6,107,357. According to these methods, the above-mentioned organic or inorganic film-forming material is mixed with a predetermined amount of a thermally decomposable porogen during film formation to form a thin film, and then the porogen is decomposed at high temperatures to form pores. U.S. Pat. Nos. 6,204,202, 6,413,882, 6,423,770 and 6,406,794 describe methods for producing a low-dielectric constant porous thin film utilizing a polyalkyleneoxide amphoteric surfactant as a porogen. According to these methods, however, pores formed in the porous thin film are partially or completely interconnected, leading to deterioration in the physical properties of the dielectric film, and chemicals used as materials of low-dielectric constant interlayer dielectric films for semiconductor devices and metal atoms are diffused into the pores. Accordingly, it is important to make the size of pores smaller and the interconnectivity of pores lower.

Fullerenes, which are sometimes called “bucky balls”, whose molecular structure resembles a soccer ball are the most recently discovered materials consisting of sixty carbon atoms (C₆₀). Bucky ball was named for Buckminster Fuller, the architect who designed the geodesic dome, because it has a similar shape to that of the dome. Fullerenes are entirely novel compounds which were discovered and isolated from sooty residue remaining after a piece of graphite was irradiated with laser beams by a group of researchers. Fullerene molecules can trap very tiny materials therein, like bird cages, and are very rigid and slippery. Further, fullerene molecules can open so that other materials can be captured and inserted therein, and can be linked in the form of a tube. Moreover, fullerenes can transmit information from computer chips via atomic-scale lines, can transport drugs necessary for the body, and can be used to produce hard and sharp cutting tools and very rigid plastics. Since fullerenes are expected to be increasingly used in various applications, scientists around the world have paid considerable attention to many potential applications for fullerenes.

On the other hand, there have been a number of suggestions regarding the formation of low-dielectric constant films in which air is incorporated using fullerenes as porogens. For example, U.S. Pat. No. 5,744,399 describes a process for lowering the dielectric constant of a layer on a semiconductor wafer by introducing a fullerene into a matrix-forming material. This process comprises the steps of forming on the wafer a composite layer comprising a matrix-forming material and a fullerene, and removing the fullerene from the composite layer to leave an open porous structure wherein the fullerene is removed by contacting the composite layer with a liquid capable of dissolving the fullerene or by oxidizing the fullerene. U.S. Pat. No. 6,287,979 describes the formation of a porous air bridge layer comprising a fullerene (buckminsterfullerene) wherein the fullerene reacts with an oxygen plasma and is removed. The former two U.S. patent publications are associated with a decrease in dielectric constant utilizing the low dielectric constant of air by incorporating a fullerene in a matrix-forming material or a layer and removing the fullerene in the subsequent step to leave pores in situ. At this time, the fullerene functions only as a porogen and does not remain in a final device. Accordingly, the mechanical strength and thermal conductivity of dielectric films for the final device are inevitably deteriorated.

In recent years, U.S. Patent Publication No. 2004/0121501 A1 mentions the introduction of a fullerene inside an interconnect insulator by using plasma-enhanced chemical vapor deposition, or possibly spin-on deposition (SOD). However, since the use of the fullerene in SOD requires dissolution of the fullerene in a solution phase, the problem arises in that since the fullerene in a solid state is not dissolved, a dispersant or an additional operation must be employed to prepare an emulsion of the fullerene. Such an emulsion limits the amount of the fullerene to be added and inevitably results in the deterioration in the roughness of the thin film.

### SUMMARY OF THE DISCLOSURE

Therefore, the present invention has been made in view of the above problems, and it is an object of the present invention to provide a composition for forming a low-dielectric constant film comprising a substituted fullerene wherein the composition can be used to form a low-dielectric constant film having superior mechanical strength and thermal conductivity.

It is another object of the present invention to provide a method for forming a low-dielectric constant film with superior mechanical strength using a fullerene by a simplified procedure at a reduced cost.

In accordance with one aspect of the present invention for achieving the above objects, there is provided a composition for forming a low-dielectric constant film which comprises a siloxane polymer, a substituted fullerene, and a solvent.

In accordance with another aspect of the present invention, there is provided a composition for forming a low-dielectric constant film which comprises at least one silane monomer, a substituted fullerene, and a solvent containing an acid or base catalyst and water.

In accordance with yet another aspect of the present invention, there is provided a method for forming a low-dielectric constant film by coating the composition comprising a substituted fullerene on a substrate, followed by curing.

The present inventors have earnestly and intensively conducted research to produce a low-dielectric constant film by forming pores in a material for forming the film (i.e. a film-forming material), and at the same time, to improve the mechanical properties and thermal conductivity of the film during and after formation of the film. As a result, the present inventors have found that the addition of a fullerene to the film-forming material was effective in the formation of a low-dielectric constant film, but the fullerene was not dissolved in a solution phase. The present inventors have made efforts to solve problems arising from the insolubility of the fullerene, and as a result, unexpectedly found that the addition of a substituted fullerene having an organic group to the film-forming material leads to the preparation of a uniform solution. By taking advantage of these findings, the dielectric constant of the film could be lowered and the mechanical properties and thermal conductivity of the film could be improved by including the substituted fullerene in the film without the removal of the substituted fullerene during or after formation of the film, thus accomplishing the present invention.

### DESCRIPTION OF THE PREFERRED EMBODIMENTS

Hereinafter, preferred embodiments of the present invention will be described in greater detail.

The present invention provides a composition for forming a low-dielectric constant film comprising about 1-70% by weight of a siloxane polymer as a film-forming material, about 0.1-10% by weight of a substituted fullerene, and the balance of a solvent. A low-dielectric constant film having superior mechanical strength can be formed by applying the composition to a substrate, followed by curing. The low-dielectric constant film thus formed can be applied as a low-dielectric semiconductor interlayer dielectric film and can be used in a wide variety of applications, including display materials, chemical sensors, biocatalysts, insulators, packaging materials, etc.

Siloxane polymers that can be used in the present invention are not specially restricted so long as they have the structure Si—O—C.

For example, the siloxane polymer used in the present invention may be a siloxane homopolymer prepared by hydrolysis and polycondensation of one monomer selected from the group consisting of a polyfunctional cyclic siloxane monomer represented by Formula 1 below: 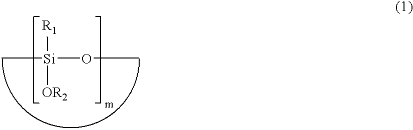
wherein R₁ is a hydrogen atom, a C₁-C₃ alkyl group, or a C₆-C₁₅ aryl group; and R₂ is a hydrogen atom, a C₁-C₁₀ alkyl group, or SiX₁X₂X₃ (in which X₁, X₂ and X₃ are each independently a hydrogen atom, a C₁-C₃ alkyl group, a C₁-C₁₀ alkoxy group, or a halogen atom); and m is an integer from 3 to 8,
a siloxane monomer having an organic bridge represented by Formula 2 or 3 below: 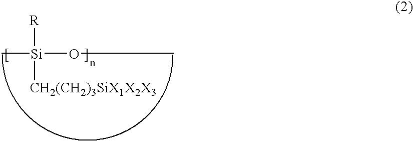
   wherein R is a hydrogen atom, a C₁-C₃ alkyl group, or a C₆-C₁₅ aryl group; X₁, X₂ and X₃ are each independently a hydrogen atom, a C₁-C₃ alkyl, a C₁-C₁₀ alkoxy, or a halogen atom, with the proviso that at least one of X₁, X₂ and X₃ is a hydrolysable functional group; m is an integer from 0 to 10; and n is an integer from 3 to 8,
   X₃X₂X₁Si—M—SiX₁X₂X₃ (3)
   wherein X₁, X₂ and X₃ are each independently a hydrogen atom, a C₁₋₃ alkyl group, a C₁-C₁₀ alkoxy group, or a halogen atom, with the proviso that at least one of X₁, X₂ and X₃ is a hydrolysable functional group; and M is a single bond, a C₁₋₁₀ alkylene group, or a C₆₋₁₅ arylene group, and
a linear alkoxy silane monomer represented by Formula 4 or 5 below:
   (R₁)ₙSi(OR₂)₄₋ₙ (4)
   wherein R₁ is a hydrogen atom, a C₁₋₃ alkyl group, a halogen atom, or a C₆₋₁₅ aryl group; R₂ is a hydrogen atom, a C₁₋₃ alkyl group, or a C₆₋₁₅ aryl group, with the proviso that at least one of R₁ and OR₂ is a hydrolysable functional group; and n is an integer from 0 to 3, 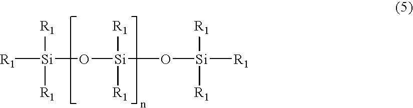
   wherein the substituents R₁ are each independently a hydrogen atom, a C₁₋₃ alkyl group, a C₁₋₁₀ alkoxy group, a hydroxyl group, or a halogen atom, with the proviso that at least one of the substituents R₁ is a hydrolysable functional group; and n is an integer from 0 to 30, in an organic solvent in the presence of water and an acid or base catalyst.

The siloxane polymer used in the present invention may be a siloxane copolymer prepared by hydrolysis and polycondensation of at least two monomers selected from the monomers of Formulae 1 to 5 in an organic solvent in the presence of water and an acid or base catalyst.

A preferred cyclic siloxane monomer of Formula 1 is the compound (TS-T4Q4) wherein R₁ is methyl, R₂ is Si(OCH₃)₃ and m is 4, represented by Formula 6 below:

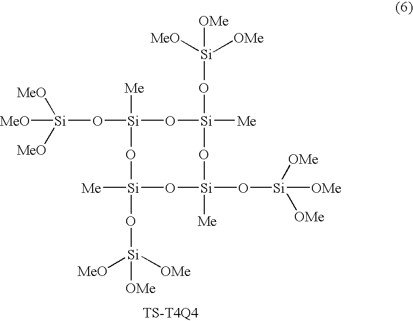

Specific examples of the alkoxy silane monomer of Formula 4 include methyltriethoxysilane, methyltrimethoxysilane, methyltri-n-propoxysilane, phenyltrimethoxysilane, phenyltriethoxysilane, phenyltrichlorosilane, phenyltrifluorosilane, phenethyltrimethoxysilane, methyltrichlorosilane, methyltribromosilane, methyltrifluorosilane, triethoxysilane, trimethoxysilane, trichlorosilane, trifluorosilane, 3,3,3-trifluoropropyl trimethoxysilane, and cyanoethyltrimethoxysilane.

Specific examples of siloxane polymers that can be used in the present invention include homopolymers of the cyclic siloxane monomer of Formula 1, and copolymers of the cyclic siloxane monomer of Formula 1 and the cyclic alkoxy silane monomer of Formula 4. In the case of the copolymers, the ratio between the monomer of Formula 1 and the monomer of Formula 4 may be in the range of 0.01:99.99 to 99.99:0.01.

The siloxane polymer used in the present invention preferably has a weight average molecular weight of about 1,000 to 100,000.

The substituted fullerene used in the present invention functions as a pore per se, and remains in the final film, thereby improving the mechanical strength and thermal conductivity of the film. In contrast, conventional porogens leave pores in a film and are then removed. Particularly, the composition of the present invention is characterized in that the substituted fullerene is used to prepare a uniform solution. The substituted fullerene used in the present invention refers to a compound in which an organic group capable of interacting with a solvent is introduced into a fullerene via a double bond reactive with the fullerene. Fullerenes are spherical allotropes of carbon. Sixty-carbon fullerenes (C₆₀) have a diameter of about 7 nm, and ninety-four-carbon fullerenes (C₉₄) have a diameter of about 11 nm. Since these fullerenes take the form of a hollow sphere, they can function as a pore per se. As explained previously, carbon atoms of fullerenes are bonded to each other to form spheres, which makes the fullerenes structurally stable. Further, it is known that covalent bonding between carbon atoms of fullerenes allows the fullerenes to have superior mechanical properties and high chemical and thermal stability.

Particularly, the substituted fullerene used in the present invention is a compound in which a reactive organic group capable of interacting with an organic solvent is introduced into a fullerene using a double bond reactive with the fullerene, and thus it has a uniform distribution in a coating solution. The reactive organic group can be selected from alkyl, hydroxyl, carboxyl, ether, aldehyde, ketone, ester, amine, amide, and the like. One or more reactive organic group can be introduced.

Specific examples of the substituted fullerene include fullerenes represented by Formulae 7 and 8 below: 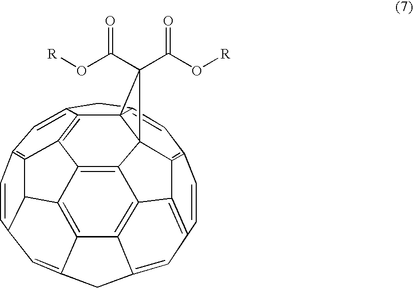
wherein the substituents R are each independently a C₁-C₂₀ alkyl group or a C₂-C₃₀ acyl group, 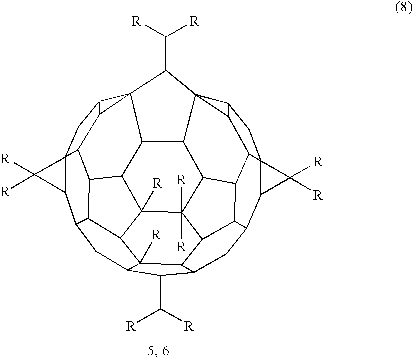
wherein the substituents R are each independently represented by Formula 9 or 10 below:

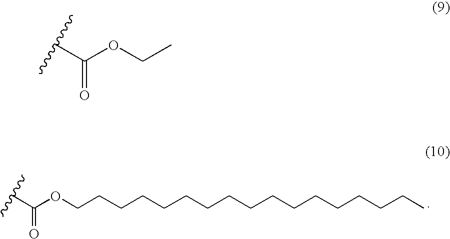

The substituent in the substituted fullerene of Formula 7 permits the fullerene molecules to be well dissolved or dispersed in a solvent, leading to uniform distribution of the fullerene in the composition. As a result, the substituted fullerene is uniformly distributed in a film during or after formation of the film, thus uniformly leaving pores in the dielectric film.

As the substituted fullerene, there may also be used [6,6]-phenyl-C61 butyric acid methyl ester (F[5,6]) of Formulae 11 and methanofullerene (1 -(3-methoxycarbonyl) propyl-1-phenyl[6,6] C₆₁ (M [6,6]) of Formulae 12 below:

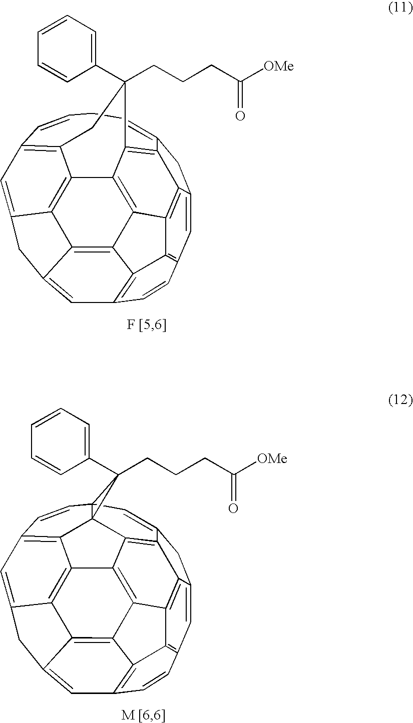

Methods for synthesizing the fullerenes of Formulae 7 and 8 are already described and known in the literature (see, Camps, X; Hirsch, A. J. Chem. Soc. Perkin trans. 1, 11, 1595 (1997)).

There is no particular restriction on the type of the solvent used in the present invention, and examples of preferred solvents include: aliphatic hydrocarbon solvents, such as hexane and heptane; aromatic hydrocarbon solvents, such as anisole, mesitylene and xylene; ketone-based solvents, such as methyl isobutyl ketone, 1-methyl-2-pyrrolidinone, cyclohexanone and acetone; ether-based solvents, such as tetrahydrofuran and isopropyl ether; acetate-based solvents, such as ethyl acetate, butyl acetate and propylene glycol methyl ether acetate; alcohol-based solvents, such as isopropyl alcohol and butyl alcohol; amide-based solvents, such as dimethylacetamide and dimethylformamide; silicon-based solvents; and mixtures thereof.

The solids content of the composition according to the present invention is not specially restricted. As described above, the composition of the present invention preferably comprises about 1-70% by weight of the siloxane polymer as a film-forming material, about 0.1-10% by weight of the substituted fullerene and the balance of the solvent, based on the total weight of the composition.

When the siloxane polymer is used in an amount exceeding 70% by weight, the solution is supersaturated and thus spin coating cannot be employed. When the content of the substituted fullerene is less than about 0.1% by weight, improvement in the effects provided by the substituted fullerene cannot be anticipated. Meanwhile, when the content of the substituted fullerene exceeds about 10% by weight, there may be problems in that the mechanical properties of the final film are deteriorated and the conductivity of the film is increased.

The present invention also provides a composition for forming a low-dielectric constant film comprising about 1-70% by weight of at least one silane monomer, about 0.1-10% by weight of a substituted fullerene, and the balance of a solvent containing an acid or base catalyst and water. The molar ratio of the silane monomer to the catalyst (an acid or a base) used is in the range of about 1:1×10⁻⁵ to about 1:10. On the other hand, the molar ratio of the silane monomer to the water used is in the range of about 1:1 to about 1:100.

The kind of the silane monomer used herein is the same as that of the monomer(s) used to prepare the siloxane polymer.

On the other hand, examples of suitable acid catalysts that can be used in the present invention include, without particular limitation, any acid catalyst known in the art. As the acid catalyst, there can be used hydrochloric acid, nitric acid, benzene sulfonic acid, oxalic acid, formic acid, or the like. As the base catalyst, there can be used potassium hydroxide, sodium hydroxide, triethylamine, sodium bicarbonate, pyridine, or the like.

The composition of the present invention may further comprise about 0.1-50% by weight of a porogen, based on the total weight of the solids.

Examples of suitable porogens that can be used in the present invention include any known porogen that can be used to form porous dielectric films, and specific examples thereof include, but are not limited to, polycaprolactone, α-cyclodextrin, β-cyclodextrin, and γ-cyclodextrin.

As the porogen, there can be used a surfactant selected from anionic surfactants, cationic surfactants, non-ionic surfactants, and block copolymers. Examples of anionic surfactants include sulfates, sulfonates, phosphates, and carboxylic acids. Examples of cationic surfactants include alkylammonium salts, gemini surfactants, cetyltrimethylpiperidinium salts, and dialkyldimethylammonium salts. Examples of non-ionic surfactants include BRij surfactants, primary amines, poly(oxyethylene) oxides, octaethylene glycol monodecyl ether, octaethylene glycol monohexadecyl ether, octylphenoxypolyethoxy (9-10) ethanol (Triton X-1 00), and block copolymers. Of these, preferred surfactants are polyethylene oxide-propylene oxide block copolymers represented by Formula 13, a polyethylene oxide-propylene oxide-polyethylene oxide triblock copolymers represented by Formula 14, cyclodextrin derivatives represented by Formula 15, cetyltrimethylammonium bromide (CTAB), octylphenoxypolyethoxy (9-10) ethanol (Triton X-100), and ethylenediaminealkoxylate block copolymers. 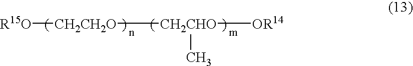
wherein R₁₄ and R₁₅ are each independently a hydrogen atom, a C₂-C₃₀ acyl group, a C₁-C₂₀ alkyl group, or a silicon (Si) compound represented by Sir₁r₂r₃ (in which r₁, r₂ and r₃ are each independently a hydrogen atom, a C₁-C₆ alkyl group, a C₁-C₆ alkoxy group, or a C₆-C₂₀ aryl group); m is an integer from 20 to 80; and n is an integer from 2 to 200. 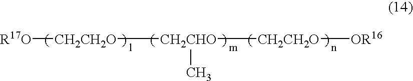
wherein R₁₆ and R₁₇ are each independently a hydrogen atom, a C₂-C₃₀ acyl group, a C₁-C₂₀ alkyl group, or a silicon compound represented by Sir₁r₂r₃ (in which r₁, r₂ and r₃ are each independently a hydrogen atom, a C₁-C₆ alkyl group, a C₁-C₆ alkoxy group, or a C₆-C₂₀ aryl group); I is an integer from 2 to 200; m is an integer from 20 to 80; and n is an integer from 2 to 200. 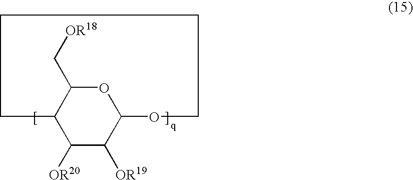
wherein R₁₈, R₁₉ and R₂₀ are each independently a hydrogen atom, a C₂-C₃₀ acyl group, a C₁-C₂₀ alkyl group, or a silicon compound represented by Sir₁r₂r₃ (in which r₁, r₂ and r₃ are each independently a hydrogen atom, a C₁-C₆ alkyl group, a C₁-C₆ alkoxy group, or a C₆-C₂₀ aryl group); and q is an integer from 5 to 8.

The present invention also provides a method for forming a low-dielectric constant film using the composition. According to the method of the present invention, a low-dielectric constant film is formed by mixing the siloxane polymer, the substituted fullerene alone or in a mixture with another porogen, and the solvent to prepare a coating solution, applying the coating solution coated to a substrate, followed by curing.

According to the method of the present invention, a low-dielectric constant film may be also formed by mixing the silane monomer, the substituted fullerene alone or in a mixture with another porogen, solvent, an acid or base catalyst and water to prepare a coating solution, applying the coating solution coated to a substrate, followed by curing.

The substrate is not specially limited so long as the objects of the present invention are not impaired. Examples of suitable substrates include any substrate capable of withstanding heat-curing conditions, for example, glass substrates, silicon wafers, and plastic substrates. These substrates can be properly selected according to intended applications.

The composition of the present invention can be applied to the substrate by common coating processes, including, but not limited to, spin coating, dip coating, spray coating, flow coating, and screen printing. In view of ease of application and uniformity, spin coating is most preferred coating process. Upon spin coating, the spin speed is preferably adjusted within the range of about 800 to 5,000 rpm. After the coating, if required, the solvent is evaporated to dry the film. The drying can be performed by simply exposing the film to the atmosphere, subjecting the film to a vacuum in the initial stage of the subsequent curing, or thermally curing the film at about 150° C. to 600° C. and preferably at about 200° C. to 450° C. for about 1-180 minutes to form a crack-free insoluble film. As used herein, by “crack-free film” is meant a film having no crack when observed under an optical microscope at a magnification of 1,000×. As used herein, by “insoluble film” is meant a film which is substantially insoluble in the solvents used for the deposition of the siloxane polymer to form the film and in any solvent described as being useful for the coating of resins. When the coating solution contains a porogen, the heat-curing temperature is properly determined taking the decomposition temperature of the porogen into consideration.

A dielectric film composed of the siloxane polymer alone has a dielectric constant not higher than 3.0 and can be used as a semiconductor dielectric low-dielectric constant coating film. The dielectric constant of a dielectric film composed of the siloxane polymer and the porogen can be controlled depending on the contents of the components. The dielectric film comprising the siloxane polymer and the substituted fullerene according to the present invention has a low dielectric constant and superior mechanical properties, including toughness, elasticity, etc. In addition, an improvement in the thermal conductivity of the dielectric film according to the present invention can be anticipated in view of inherent characteristics of the fullerene. Accordingly, the dielectric film of the present invention can be useful as a semiconductor interlayer dielectric film.

Preferred embodiments of the present invention will now be described in detail with reference to the following examples. However, these examples are given for the purpose of illustration and are not to be construed as limiting the scope of the invention.

### PREPARATIVE EXAMPLE 1

### Polyfunctional cyclic siloxane monomer

41.6 mmol (10.00 g) of 2,4,6,8-tetramethyl-2,4,6,8-cyclotetrasiloxane was diluted with 100 ml of tetrahydrofuran in a flask, and then 700 mg of 10 wt % palladium/charcoal (Pd/C) was added thereto. Subsequently, 177.8 mmol (3.20 ml) of distilled water was added to the mixture to evolve hydrogen gas. After the hydrogen gas was removed, the reaction was allowed to proceed at room temperature for 5 hours. The reaction solution was filtered through celite and MgSO₄. The obtained filtrate was diluted with 200 ml of tetrahydrofuran (THF), and then 177.8 mmol (13.83 g) of triethylamine was added thereto. After the resulting solution was cooled to 0° C., 177.8 mmol (25.0 g) of chlorotrimethoxysilane was slowly added thereto. The resulting mixture was allowed to warm to room temperature. The mixture was reacted for 12 hours. The reaction solution was filtered through celite, and the obtained filtrate was concentrated at a reduced pressure of about 0.1 torr to remove volatile materials, thereby making possible the colorless liquid monomer of Formula 6 below:

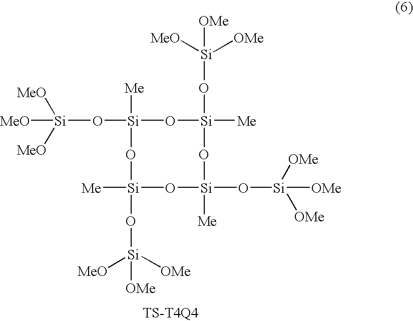

The analytical results of the ¹H-NMR spectrum (300 MHz) of the monomer are as follows: δ 0.092 (s, 12H, 4×[—CH₃]), 3.58 (s, 36H, 4×[—OCH₃]).

### Synthesis of Siloxane Polymer (A)

After 65.09 mmol of the polyfunctional siloxane monomer prepared in Preparative Example 1 and 20.36 mmol of methyltrimethoxysilane (MTMS) were placed in a flask, the mixture was diluted with tetrahydrofuran until the concentration of the solution was 0.05 to 0.07M. The reaction solution was cooled to −78° C. 1.222 mmol of hydrochloric acid and 407.2 mmol of water were added to the flask. The reaction temperature was gradually increased to 70° C. At this temperature, the reaction was continued for 16 hours. The reaction solution was transferred to a separatory funnel, followed by the addition of diethyl ether in the same amount as that of the initially added tetrahydrofuran along with tetrahydrofuran. The resulting mixture was washed three times with water in the amount of one tenth of the total volume of the solvents used, and was then concentrated at reduced pressure to remove volatile materials, giving a polymer in the form of a white powder. The polymer was dissolved in tetrahydrofuran until it became transparent, and was filtered through a filter (pore size: 0.2 μm). Water was slowly added to the filtrate to obtain a precipitate in the form of a white powder. The precipitate was dried at 0˜20° C. and 0.1 torr for 10 hours to provide 4.0 g of a siloxane polymer. The contents of Si—OH, Si—OCH₃ and Si—CH₃ in the polymer were measured to be 33.80%, 1.10%, and 65.10%, respectively. The contents (%) of Si—OH, Si—OCH₃ and Si—CH₃ in the siloxane polymer were determined by nuclear magnetic resonance (NMR, Bruker) analysis.

Si—OH (%)=Area (Si—OH)×[Area (Si—OH)+Area (Si—OCH₃)/3+Area (Si—CH₃)/3]×100.

Si—OCH₃ (%)=Area (Si—OCH₃)/3+[Area (Si—OH)+Area (Si—OCH₃)/3+Area (Si—CH₃)/3]×100.

Si—CH₃ (%)=Area (Si—CH₃)/3+[Area (Si—OH)+Area (Si—OCH₃)/3+Area (Si—CH₃)/3]×100.

### Synthesis of Siloxane Polymer (B)

2.30 g of siloxane polymer (B) was synthesized in the same manner as in the synthesis of siloxane polymer (A), except that 10 mmol of the polyfunctional siloxane monomer of Formula 6 alone prepared in Preparative Example 1 was used. At this time, 4.055 mmol of HCl and 1351.4 mmol of water were used. As a result, the contents of Si—OH, Si—OCH₃ and Si—CH₃ in the polymer were measured to be 43.5%, 0.6% and 55.9%, respectively.

### Synthesis of Substituted Fullerene Compounds

32 μl (0.415 mmol) of 1,8-diazabicyclo[5,4,0]undecene-7 (DBU) was added to a mixture of 100 mg of C₆₀ (0.139 mmol), 69 mg (0.208 mmol) of CBr₄ and 0.208 mmol of malonate. After 6 hours of the addition, the reaction mixture was purified by chromatography, providing the first modified fullerene of Formula 7. The second modified fullerene of Formula 8 was prepared by the following procedure. First, a mixture of 100 mg of C₆₀ (0.139 mmol) and 0.286 g (1.39 mmol) of dimethyl amine (DMA) was stirred in 60 ml of toluene at room temperature for 2 hours. 0.460 g (1.39 mmol) of CBr₄ and 10 equivalents of malonate were added to the mixture, and then 0.414 ml (2.78 mmol) of 1,8-diazabicyclo[5,4,0]undecene-7 (DBU) was added dropwise thereto. The obtained mixture was purified by chromatography, giving the desired fullerene.

### EXAMPLES

### Examples A-1 To A-4

### Formation of Dielectric Films A-1 To A-4

0.611 g of polymer (A) as a siloxane polymer and 6 mg (1 % by weight relative to the polymer) of the hexasubstituted modified fullerene of Formula 8 as an additive were added to propylene glycol methyl ether acetate as a solvent to prepare a coating solution having a solid content of 24 wt %. The coating solution was spin-coated on a silicon wafer at 2,000 rpm for 30 seconds, sequentially pre-heated on a hot plate under a nitrogen atmosphere at 150° C. for one minute and at 250° C. for one minute, and dried to form a film. The film was heated to 420° C. at a rate of 3° C./min. under vacuum for one hour to form a dielectric film A-1.

Dielectric films A-2, A-3 and A-4 were formed in the same manner as above, except that 12 mg (2% by weight relative to the polymer), 31 mg (5% by weight relative to the polymer) and 61 mg (10% by weight relative to the polymer) of the hexasubstituted modified fullerene of Formula 8 were used, respectively.

The thickness, refractive index, dielectric constant, hardness, elastic modulus and carbon content of the dielectric films were measured. The results are shown in Table 1.

First, the physical properties of the dielectric films were evaluated in the following procedures.

### Evaluation of Physical Properties

1) Measurement of Dielectric Constant

First, a thermal silicon oxide film was coated to a thickness of 3,000 Å on a boron-doped p-type silicon wafer, and then a 100 Å-thick titanium film, a 2,000 Å-thick aluminum film and a 100 Å-thick film were sequentially deposited on the silicon oxide film using a metal evaporator. Thereafter, a dielectric film was formed on the resulting structure, after which a 100 Å-thick circular titanium thin film (diameter: 1 mm) and a 5,000 Å-thick aluminum thin film (diameter: 1 mm) were sequentially deposited on the dielectric film using a hardmask designed so as to have an electrode diameter of 1 mm, to form a low-dielectric constant film having a MIM (metal-insulator-metal) structure. The dielectric constant of the low-dielectric constant film was measured. The capacitance of the thin film was measured around 10 kHz, 100 kHz and 1 MHz using a PRECISION LCR METER (HP4284A) accompanied with a probe station (Micromanipulatior 6200 probe station), and the thickness of the thin film was measured using a prism coupler. The dielectric constant of the thin film was calculated according to the following equation:
k=C×d/εₒ×A
in which k is the relative permittivity, C is the capacitance, εₒ is the dielectric constant of a vacuum (8.8542×10⁻¹² Fm⁻¹), d is the thickness of the dielectric film, and A is the contact cross-sectional area of the electrode.

2) Thickness And Refractive Index

The thickness and refractive index of the thin films were measured using an elipsometor and a prism coupler, respectively.

3) Hardness And Elastic Modulus

The hardness and elastic modulus of the dielectric thin films were determined by quantitative analysis using a Nanoindenter II (MTS). Specifically, after the nanoindenter was indented into the thin films until the indentation depth reached 10% of its overall thickness, the hardness and modulus of the thin films were measured. The thickness of the thin films was measured using a prism coupler. To ensure better reliability of the measurement in the following examples and comparative examples, the hardness and modulus were measured at a total of 6 indention points on the dielectric films, and the obtained values were averaged.

### Examples B-1 To B-4

### Formation of Dielectric Films B-1 To B-4

Dielectric constant films B-1 to B-4 were formed in the same manner as in the formation of dielectric films A-1 to A-4, except that the weight of polymer (A) was changed from 0.611 g to 0.550 g, and 0.061 g of heptakis(2,3,6-tri-O-methyl)-β-cyclodextrin (tCD) was added as another porogen. At this time, the weights of the modified fullerene used to form dielectric constant films B-1 to B-4 were the same as those of the modified fullerene used to form dielectric constant films A-1 to A-4, respectively. The thickness, refractive index, dielectric constant, hardness, elastic modulus and carbon content of the dielectric films were measured. The results are shown in Table 1.

### Examples C-1 To C4

### Formation of Dielectric Films C-1 To C4

Dielectric constant films C-1 to C-4 were formed in the same manner as in the formation of dielectric films A-1 to A-4, except that the weight of polymer (A) was changed from 0.611 g to 0.489 g, and 0.122 g of heptakis(2,3,6-tri-O-methyl)-β-cyclodextrin (tCD) was added as another porogen. At this time, the weights of the modified fullerene used to form dielectric constant films C-1 to C-4 were the same as those of the modified fullerene used to form dielectric constant films A-1 to A-4, respectively. The thickness, refractive index, dielectric constant, hardness, elastic modulus and carbon content of the dielectric films were measured. The results are shown in Table 1.

### Examples of D-1 To D-4

### Formation of Dielectric Films D-1 To D-4

Dielectric constant films D-1 to D-4 were formed in the same manner as in the formation of dielectric films A-1 to A-4, except that polymer (B) was used instead of polymer (A). The thickness, refractive index, dielectric constant, hardness, elastic modulus and carbon content of the dielectric films were measured. The results are shown in Table 1.

### Comparative Examples A To D

### Formation of Dielectric Films A To D

Dielectric constant films A to D were formed in the same manner as in the formation of dielectric films A-1 to A-4, except that no substituted fullerene was added. The thickness, refractive index, dielectric constant, hardness, elastic modulus and carbon content of the dielectric films were measured. The results are shown in Table 1.

TABLE 1

| | Physical Properties | | | | |
|---|---|---|---|---|---|
| | | Dielectric | | | |
| | Refractive | constant | | Elastic | Thickness |
| Example No. | index (RI) | (k) | Hardness | Modulus | (Å) |
| Comparative | 1.379 | 2.83 | 1.35 | 9.23 | 4,712 |
| Example A | | | | | |
| Example A-1 | 1.384 | 2.76 | 1.47 | 9.07 | 4,836 |
| Example A-2 | 1.388 | 2.83 | 1.48 | 9.36 | 5,018 |
| Example A-3 | 1.400 | 2.87 | 1.42 | 9.08 | 5,759 |
| Example A-4 | 1.418 | 2.81 | 1.11 | 7.48 | 5,997 |
| Comparative | 1.338 | 2.64 | 1.16 | 8.00 | 4,789 |
| Example B | | | | | |
| Example B-1 | 1.341 | 2.45 | 1.25 | 8.35 | 5,165 |
| Example B-2 | 1.348 | 2.64 | 1.23 | 7.93 | 5,571 |
| Example B-3 | 1.351 | 2.56 | 1.10 | 7.34 | 5,672 |
| Example B-4 | 1.367 | 2.67 | 0.98 | 6.41 | 5,976 |
| Comparative | 1.307 | 2.06 | 0.50 | 3.75 | 4,395 |
| Example C | | | | | |
| Example C-1 | 1.298 | 2.04 | 0.52 | 3.83 | 4,574 |
| Example C-2 | 1.300 | 1.99 | 0.54 | 3.96 | 4,672 |
| Example C-3 | 1.311 | 1.97 | 0.53 | 4.15 | 5,064 |
| Example C-4 | 1.338 | 2.07 | 0.52 | 4.15 | 5,571 |
| Comparative | 1.395 | 3.31 | 2.30 | 14.62 | 6,355 |
| Example D | | | | | |
| Example D-1 | 1.395 | 3.25 | 2.34 | 14.43 | 6,298 |
| Example D-2 | 1.399 | 3.20 | 2.27 | 14.33 | 6,468 |
| Example D-3 | 1.409 | 3.28 | 1.94 | 12.85 | 6,670 |
| Example D-4 | 1.436 | 2.81 | 1.88 | 12.49 | 7,080 |

As can be seen from the data shown in Table 1, the dielectric films formed in the examples using the compositions of the present invention have a low dielectric constant despite a small thickness, compared to the dielectric films comprising no substituted fullerene formed in the comparative examples. Accordingly, the substituted fullerene can function as a porogen to form pores in the films.

It is obvious from the results shown in Table 1 that when the substituted fullerene was added alone or in combination with the conventional porogen (tCD), low-dielectric constant films could be formed. When the substituted fullerene was added in an amount of 1% by weight, the dielectric constant of the dielectric films was lowered and the mechanical properties of the films were improved. In addition, when the substituted fullerene was added in an amount exceeding 1% by weight, it did not greatly affect the reduction in dielectric constant and remained unremoved during formation of the films, thereby lowering the dielectric constant due to the formation of pores resulting from the substituted fullerene and improving the mechanical properties. Specific experimental values regarding the thermal conductivity of the dielectric films were not obtained, but it is assumed that an improvement in the thermal conductivity of the dielectric films from the improved mechanical properties is anticipated in view of inherent characteristics of the substituted fullerene.

As apparent from the above description, since the substituted fullerene included in the composition for forming a low-dielectric constant film according to the present invention is highly soluble in a solvent, a uniform solution can be prepared despite the addition of a large amount of the fullerene. In addition, the substituted fullerene advantageously lowers the dielectric constant of a thin film and improves the mechanical properties, such as hardness and elastic modulus, of the thin film. Furthermore, the substituted fullerene used in the present invention contributes to the reduction in dielectric constant and the improvement in mechanical properties despite the addition of an extremely small amount of the fullerene. Moreover, an improvement in thermal conductivity can be anticipated in view of inherent characteristics of the fullerene.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A composition for forming a low-dielectric constant film comprising about 1-70% by weight of a siloxane polymer, about 0.1-10% by weight of a substituted fullerene, and the balance of a solvent.

2. The composition according to claim 1, wherein the siloxane polymer is prepared by hydrolysis and polycondensation of at least one monomer selected from the group consisting of monomers represented by Formulae 1 to 5 below: 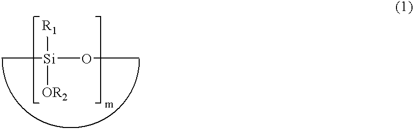
wherein R₁ is a hydrogen atom, a C₁-C₃ alkyl group, or a C₆-C₁₅ aryl group; and R₂ is a hydrogen atom, a C₁-C₁₀ alkyl group, or SiX₁X₂X₃ (in which X₁, X₂ and X₃ are each independently a hydrogen atom, a C₁-C₃ alkyl group, a C₁-C₁₀ alkoxy group, or a halogen atom); and m is an integer from 3 to 8, 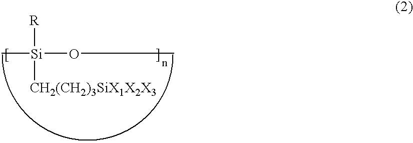
wherein R is a hydrogen atom, a C₁-C₃ alkyl group, or a C₆-C₁₅ aryl group; X₁, X₂ and X₃ are each independently a hydrogen atom, a C₁-C₃ alkyl, a C₁-C₁₀ alkoxy, or a halogen atom, with the proviso that at least one of X₁, X₂ and X₃ is a hydrolysable functional group; m is an integer from 0 to 10; and n is an integer from 3 to 8,
X₃X₂X₁Si—M—SiX₁X₂X₃ (3)
wherein X₁, X₂ and X₃ are each independently a hydrogen atom, a C_{1˜3} alkyl group, a C_{1˜10} alkoxy group, or a halogen atom, with the proviso that at least one of X₁, X₂ and X₃ is a hydrolysable functional group; and M is a single bond, a C_{1˜10} alkylene group, or a C_{6˜15} arylene group,
(R₁)ₙSi(OR₂)₄₋ₙ (4)
wherein R₁ is a hydrogen atom, a C_{1˜3} alkyl group, a halogen atom, or a C_{6˜15} aryl group; R₂ is a hydrogen atom, a C_{1˜3} alkyl group, or a C_{6˜15} aryl group, with the proviso that at least one of R₁ and OR₂ is a hydrolysable functional group; and n is an integer from 0 to 3, 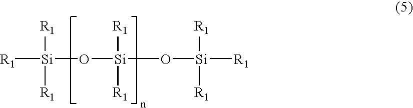
wherein the substituents R₁ are each independently a hydrogen atom, a C_{1˜3} alkyl group, a C₁₋₁₀ alkoxy group, a hydroxyl group, or a halogen atom, with the proviso that at least one of the substituents R₁ is a hydrolysable functional group; and n is an integer from 0 to 30, in an organic solvent in the presence of water and an acid or base catalyst.

3. The composition according to claim 1, wherein the siloxane polymer has a weight average molecular weight of about 1,000 to 100,000.

4. The composition according to claim 1, wherein the substituted fullerene has at least one functional group selected from the group consisting of alkyl, alcohol, carboxyl, ether, aldehyde, ketone, ester, amine, and amide.

5. The composition according to claim 4, wherein the substituted fullerene is a compound of Formula 7, 8, 11 or 12 below: 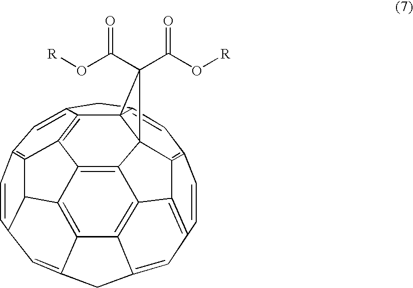
wherein the substituents R are each independently a C₁-C₂₀ alkyl group or a C₂-C₃₀ acyl group, 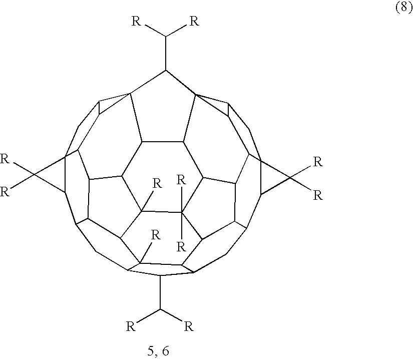
wherein the substituents R are each independently represented by Formula 9 or 10 below:

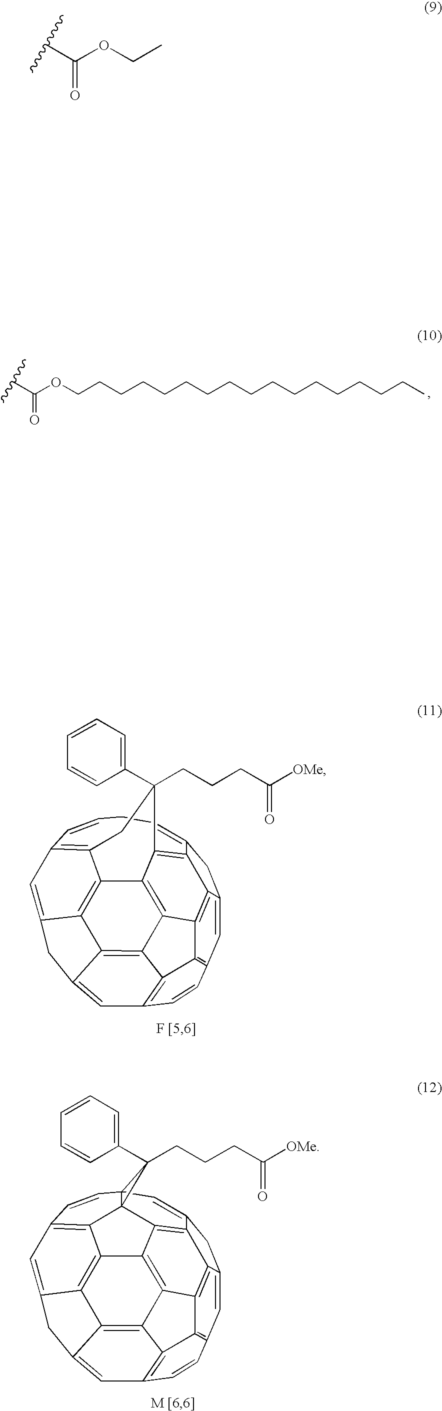

6. The composition according to claim 1, wherein the solvent is selected from the group consisting of aliphatic hydrocarbon solvents, aromatic hydrocarbon solvents, ketone-based solvents, ether-based solvents, acetate-based solvents, alcohol-based solvents, amide-based solvents, silicon-based solvents, and mixtures thereof.

7. The composition according to claim 1, further comprising about 0.1-50% by weight of a porogen.

8. The composition according to claim 7, wherein the porogen is selected from the group consisting of polycaprolactone, α-cyclodextrin, β-cyclodextrin and γ-cyclodextrin, or is selected from the group consisting of sulfates, sulfonates, phosphates, carboxylic acids, alkylammonium salts, gemini surfactants, cetyltrimethylpiperidinium salts, dialkyldimethylammonium salts, BRij surfactants, primary amines, poly(oxyethylene) oxides, octaethylene glycol monodecyl ether, octaethylene glycol monohexadecyl ether, octylphenoxypolyethoxy (9-10) ethanol (Triton X-100), and polyethylene oxide-propylene oxide-polyethylene oxide block copolymers.

9. A composition for forming a low-dielectric constant film comprising about 1-70% by weight of at least one silane monomer, about 0.1-10% by weight of a substituted fullerene, and the balance of a solvent containing an acid or base catalyst and water.

10. The composition according to claim 9, wherein the substituted fullerene has at least one functional group selected from the group consisting of alkyl, alcohol, carboxyl, ether, aldehyde, ketone, ester, amine, and amide.

11. The composition according to claim 9, wherein the substituted fullerene is a compound of Formula 7, 8, 11 or 12 below: 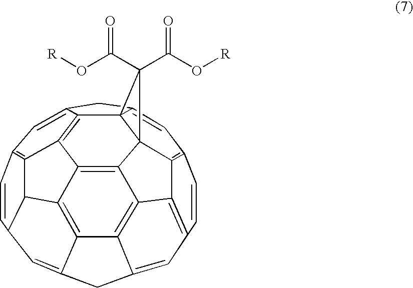
wherein the substituents R are each independently a C₁-C₂₀ alkyl group or a C₂-C₃₀ acyl group, 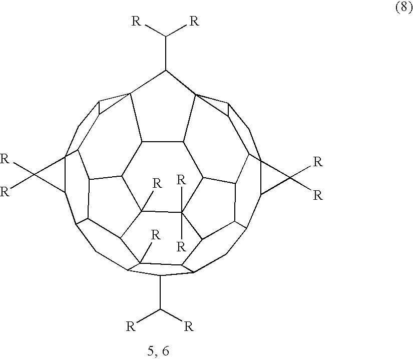
wherein the substituents R are each independently represented by Formula 9 or 10 below:

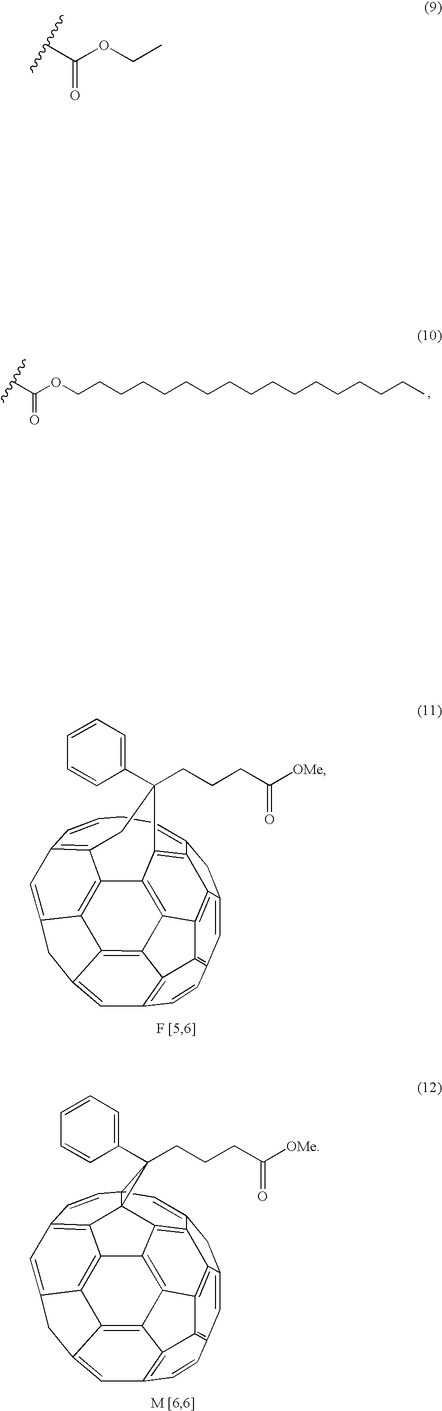

12. The composition according to claim 9, wherein the acid catalyst is selected from the group consisting of hydrochloric acid, nitric acid, benzene sulfonic acid, oxalic acid, formic acid, and mixtures thereof; the base catalyst is selected from the group consisting of sodium hydroxide, tetramethylammonium hydroxide (TPAOH), potassium hydroxide, and mixtures thereof.

13. The composition according to claim 9, further comprising about 0.1-50% by weight of a porogen.

14. The composition according to claim 13, wherein the porogen is selected from the group consisting of polycaprolactone, α-cyclodextrin, β-cyclodextrin and γ-cyclodextrin, or is selected from the group consisting of sulfates, sulfonates, phosphates, carboxylic acids, alkylammonium salts, gemini surfactants, cetyltrimethylpiperidinium salts, dialkyldimethylammonium salts, BRij surfactants, primary amines, poly(oxyethylene) oxides, octaethylene glycol monodecyl ether, octaethylene glycol monohexadecyl ether, octylphenoxypolyethoxy (9-10) ethanol (Triton X-100), and polyethylene oxide-propylene oxide-polyethylene oxide block copolymers.

15. A method for forming a low-dielectric constant film by coating the composition according to claim 1, on a substrate, followed by curing.

16. The method according to claim 15, wherein the coating is conducted by spin coating, dip coating, spray coating, flow coating, or screen printing.

17. The method according to claim 15, wherein the curing is conducted by thermal curing at about 150-600° C. for about 1-180 minutes.

18. A semiconductor interlayer dielectric film formed using the composition according to claim 1.

19. A method for forming a low-dielectric constant film by coating the composition according to claim 7, on a substrate, followed by curing.

20. A method for forming a low-dielectric constant film by coating the composition according to claim 9 on a substrate, followed by curing.

21. A method fofororming a low-dielectric constant film by coating the composition according to claim 13 on a substrate, followed by curing.
